(19) United States
(12) Patent Application Publication
(10) Pub. No.: US 2008/0122548 A1
(43) Pub. Date: May 29, 2008

(54) OSCILLATOR USING SCHMITT TRIGGER CIRCUIT

(75) Inventors: Ha Woong JEONG, Gyeonggi-do (KR); Kyoung Soo Kwon, Gyeonggi-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., GYUNGGI-DO (KR)

(21) Appl. No.: 11/942,530

(22) Filed: Nov. 19, 2007

(30) Foreign Application Priority Data
Nov. 20, 2006 (KR) 10-2006-0114747

(51) Int. Cl. H03L 1/00

(52) U.S. Cl. 331/175

(57) ABSTRACT

Provided is an oscillator using a Schmitt trigger circuit, the oscillator including a constant current generating section that generates a current with a constant magnitude; a current mirroring section that is connected to the constant current generating section and mirrors the current generated by the constant current generating section; a control section that is connected to the current mirroring section and supplies or blocks the current applied through the current mirroring section; a capacitor of which one end is connected to the control section and the other end is grounded, the capacitor being charged with a current supplied by the control section; a Schmitt trigger circuit that receives the voltage charged in the capacitor so as to output a high- or low-level voltage; and a voltage delay section that is connected to the Schmitt trigger circuit and delays the voltage output by the Schmitt trigger circuit to output.

### CROSS-REFERENCE TO RELATED APPLICATIONS

This application claims the benefit of Korean Patent Application No. 10-2006-0114747 filed with the Korea Intellectual Property Office on Nov. 20, 2006, the disclosure of which is incorporated herein by reference.

### BACKGROUND OF THE INVENTION

1. Field of the Invention

The present invention relates to an oscillator using a Schmitt trigger circuit, which uses a Schmitt trigger circuit having a comparator and a constant current source for generating a constant current so as to output an oscillation signal with a constant frequency despite a change in surrounding environment such as temperature or voltage.

2. Description of the Related Art

In general, oscillators serve to generate clocks for driving a central processing unit (CPU) and various memory elements, that is, oscillation signals with a constant frequency.

Such oscillators can maintain the frequency stability of an oscillation signal so as to generate a constant frequency, regardless of a change in surrounding environment such as temperature or voltage.

Hereinafter, a conventional oscillator will be described with reference to accompanying drawings.

FIG. 1 is a circuit diagram of a conventional oscillator using delay cells.

As shown in FIG. 1, the oscillator has first to fourth delay cells L1 to L4, a constant current source 110, a control section 120, a PMOS transistor section 130, and an NMOS transistor section 140.

The constant current source 110 generates a constant current I₀ regardless of a change in surrounding environment such as temperature or voltage.

The control section 120 is composed of first to third control sections 121 to 123 and is connected to the PMOS transistor section 130 and the NMOS transistor section 140. The control section 120 receives an oscillation signal Vout output from the oscillator so as to select a voltage applied from the PMOS transistor section 130 or is connected to the NMOS transistor section 140 so as to ground the oscillation signal Vout.

The first control section 121 is composed of a PMOS transistor PM5 and an NMOS transistor NM5. The second control section 122 is composed of a PMOS transistor PM6 and an NMOS transistor NM6. The third control section 123 is composed of a PMOS transistor PM7 and an NMOS transistor NM7.

The PMOS transistor section 130 is composed of first to fourth PMOS transistors PM1 to PM4, of which the gates are connected to each other, and the drains are connected to a power supply VDD for driving the oscillator. Further, the source of the first PMOS transistor PM1 is connected to the constant current source 110 so as to supply a driving voltage VDD to the constant current source 110, and the sources of the second to third PMOS transistors PM2 to PM4 are connected to the control unit 120 so as to supply a driving voltage VDD to the control unit 120.

The NMOS transistor section 140 is composed of first to fourth NMOS transistors NM1 to NM4, of which the gates are connected to each other, the drains are connected to the constant current source 110 and the control section 120, respectively, and the sources are grounded so as to ground the constant current source 110 and the control section 120.

When the oscillation signal Vout of the oscillator is a low-level signal, the first control section 121 receives the low-level oscillation signal Vout such that the fifth PMOS transistor PM5 of the first control section 121 is turned on and the fifth NMOS transistor NM5 thereof is turned off.

The fifth PMOS transistor PM5 receives a high-level driving voltage applied through the second PMOS transistor PM2 and then delivers the high-level driving voltage to the second control section 122.

In the second control section 122 receiving the high-level voltage, the sixth PMOS transistor PM6 is turned off, and the sixth NMOS transistor NM6 is turned on. As the sixth NMOS transistor NM6 is grounded through the third NMOS transistor NM3 of the NMOS transistor section 140, the sixth NMOS transistor NM6 delivers a low-level voltage to the third control section 123.

In the third control section 124 receiving the low-level voltage, the seventh PMOS transistor PM7 is turned on, and the seventh NMOS transistor NM7 is turned off. The seventh PMOS transistor PM7 receives a high-level driving voltage through the fourth PMOS transistor PM4 of the PMOS transistor section 130 so as to output as an oscillation signal Vout. Therefore, when a low-level oscillation signal Vout is applied, the low-level oscillation signal Vout is transferred into a high-level oscillation signal Vout to output.

Further, when the oscillation signal Vout is a high-level signal, the fifth NMOS transistor NM5, the fifth PMOS transistor PM5, and the seventh NMOS transistor NM7 are sequentially turned on so as to transfer the oscillation signal Vout into a low-level signal to output.

At this time, in the oscillator using the delay cells L1 to L4, delay time is determined by an amount of current flowing in each of the delay cells L1 to L4. Therefore, if an amount of current flowing in each of the delay cells L1 to L4 can be constantly maintained, the oscillation signal Vout can maintain a constant frequency.

However, when a driving voltage supplied to each of the delay cells L1 to L4 is varied, an amount of current I₀ flowing in each of the delay cells L1 to L4 is changed. Therefore, the frequency of the oscillation signal Vout is not maintained constantly, but is varied.

FIG. 2 is a circuit diagram of another conventional oscillator using a Schmitt trigger circuit. As shown in FIG. 2, the conventional oscillator includes first and second cell lines L1 and L2, a control section 210, a PMOS transistor section 220, an NMOS transistor section 230, a capacitor C, a Schmitt trigger circuit 240, and an inverter 250.

The PMOS transistor section 220 is composed of first and second PMOS transistors PM1 and PM2, of which the gates are connected to each other and the drains are connected to a power supply VDD for driving the oscillator. The source of the first PMOS transistor PM1 is connected to the NMOS transistor section 230, and the source of the second PMOS transistor PM2 is connected to the control section 210.

The NMOS transistor section 230 is composed of first and second NMOS transistors NM1 and NM2, of which the gates are connected to each other and the sources are grounded. The drain of the first NMOS transistor NM1 is connected to the source of the first PMOS transistor PM1, and the drain of the second NMOS transistor NM2 is connected to the control section 210.

The control section 210 is composed of a third PMOS transistor PM3 and a third NMOS transistor NM3. As any one of the third PMOS transistor PM3 and the third NMOS transistor NM3 is turned on by the oscillation signal Vout, the control section 210 outputs a high-level driving voltage or low-level ground voltage.

The gate of the third PMOS transistor PM3 receives an oscillation signal Vout of the oscillator, the drain thereof is connected to the source of the second PMOS transistor PM2, and the source thereof is connected to the drain of the third NMOS transistor NM3.

The gate of the third NMOS transistor NM3 receives an oscillation signal Vout of the oscillator, and the source thereof is connected to the drain of the second NMOS transistor NM2.

One end of the capacitor C is connected to a contact point N1 between the source of the third PMOS transistor PM3 and the drain of the third NMOS transistor NM3, and the other end thereof is grounded so as to be charged with a voltage output from the control section 210.

The Schmitt trigger circuit 240 is connected to the contact point N1 so as to receive the voltage of the contact point N1 charged in the capacitor C. When the voltage of the contact point N1 is more than a high transition voltage which is the minimum voltage for outputting a high-level voltage, the Schmitt trigger circuit 240 outputs a high-level voltage. When the voltage of the contact point N1 is less than a low transition voltage which is the maximum voltage for outputting a low-level voltage, the Schmitt trigger circuit 240 outputs a low-level voltage.

The inverter 250 receives the voltage output from the Schmitt trigger circuit 240 and then transfers the state of the voltage. Then, a pulse-type square-wave oscillation signal Vout is output.

FIG. 3 is a circuit diagram of the Schmitt trigger circuit used in the oscillator. As shown in FIG. 3, the Schmitt trigger circuit 240 includes fourth to sixth PMOS transistors PM4 to PM6 and fourth to sixth NMOS transistors NM4 to NM6. The fourth and fifth PMOS transistors PM4 and PM5 and the fourth and fifth NMOS transistors NM4 and NM5 are connected to each other on one cell line L3. The source of the sixth PMOS transistor PM6 is connected to a contact point between the fourth and fifth PMOS transistors PM4 and PM5, and the drain thereof is grounded. The source of the sixth NMOS transistor NM6 is connected to a contact point between the fourth and fifth NMOS transistors NM4 and NM5, and the drain thereof is connected to the power supply VDD.

When an input voltage Vin applied from outside is higher than the high transition voltage V_{H}, the fourth and fifth NMOS transistors NM4 and NM5 of the Schmitt trigger circuit 240 are turned on so as to be grounded. Then, a low-level output voltage Vo is output.

Further, when the input voltage Vin is lower than the low transition voltage V_{L}, the fourth and fifth PMOS transistors PM4 and PM5 of the Schmitt trigger circuit 240 are turned on so as to output the high-level driving voltage VDD as an output voltage Vo.

FIG. 4 is a diagram showing the waveform of the Schmitt trigger circuit 240. As shown in FIG. 4, when the input voltage Vin increases from a voltage less than the high transition voltage V_{H} to a voltage more than the high transition voltage V_{H}, a high-level output voltage Vo is output after the high transition voltage V_{H} is applied. When the input voltage Vin decreases from a voltage more than the low transition voltage V_{L} to a voltage less than the low-transition voltage V_{L}, a low-level output voltage Vo is output after the low transition voltage V_{L} is applied.

Therefore, the Schmitt trigger circuit 240 receives a sine-wave input voltage Vin and then transforms the input voltage Vin into a pulse-type square-wave voltage. Therefore, the Schmitt trigger circuit 240 can output an output voltage Vo with a constant frequency.

FIG. 5 is a diagram showing the output voltage waveform of the conventional oscillator using a Schmitt trigger circuit. In FIG. 5, t1 and t2 represent the magnitude of frequency. Referring to FIG. 5, t1 and t2 can be expressed by Equations 1 to 3.

$${t}_{1} = C \times \frac{{V}_{H} - {V}_{L}}{{I}_{0}} \qquad [ Equation 1 ]$$

Here, C represents the capacitance of the capacitor C.

$$\begin{matrix}{t}_{2} = C \times \frac{{V}_{H} - {V}_{L}}{{I}_{0}} & [ Equation 2 ] \\ {f}_{out} = \frac{1}{{t}_{1} + {t}_{2}} & [ Equation 3 ]\end{matrix}$$

Here, fₒᵤₜ represents the frequency of an oscillation signal Vout.

As expressed in Equations 1 to 3, t1 and t2 are affected by the high transition voltage V_{H} and the low transition voltage V_{L}.

The high transition voltage V_{H} and the low transition voltage V_{L} can be expressed by Equations 4 and 5.

$$\frac{{β}_{1}}{{β}_{3}} = {[ \frac{VDD - {V}_{H}}{{V}_{H} - {V}_{TH}} ]}^{2} \qquad [ Equation 4 ]$$

Here, β₁ and β₃ represent the capacity of the fifth and sixth NMOS transistors NM5 and NM6, and V_{TH} represents a threshold voltage.

$$\frac{{β}_{5}}{{β}_{6}} = {[ \frac{{V}_{L}}{VDD - {V}_{L} - {V}_{TH}} ]}^{2} \qquad [ Equation 5 ]$$

Here, β₅ and β₆ represent the capacity of the fifth and sixth PMOS transistors PM5 and PM6.

That is, it can be found that the high transition voltage V_{H} and the low transition voltage V_{L} are affected by the power supply VDD and the threshold voltage V_{TH}. Here, the threshold voltage V_{TH} is associated with the temperature. Therefore, when the surrounding temperature changes, the high transition voltage V_{H} or the low transition voltage V_{L} changes from a normal high or low transition voltage V_{H1} or V_{L1} to a high or low transition voltage V_{H2} or V_{L2} depending on the surrounding environment, while a constant voltage is not maintained.

Accordingly, although a high-level oscillation signal A′ should be output at a point of time A and a low-level oscillation signal B′ should be output at a point of time B, a high-level oscillation signal E′ is output at a point of time E, and a low-level oscillation signal F′ is output at a point of time F. Therefore, the frequency of the oscillation signal Vout is not maintained constantly, but is varied.

### SUMMARY OF THE INVENTION

An advantage of the present invention is that it provides an oscillator using a Schmitt trigger circuit, which uses a Schmitt trigger circuit having a comparator and a constant current source for generating a constant current so as to output an oscillation signal with a constant frequency despite a change in surrounding environment such as temperature or voltage.

Additional aspects and advantages of the present general inventive concept will be set forth in part in the description which follows and, in part, will be obvious from the description, or may be learned by practice of the general inventive concept.

According to an aspect of the invention, an oscillator using a Schmitt trigger circuit comprises a constant current generating section that generates a current with a constant magnitude; a current mirroring section that is connected to the constant current generating section and mirrors the current generated by the constant current generating section; a control section that is connected to the current mirroring section and supplies or blocks the current applied through the current mirroring section; a capacitor of which one end is connected to the control section and the other end is grounded, the capacitor being charged with a current supplied by the control section; a Schmitt trigger circuit that receives the voltage charged in the capacitor so as to output a high- or low-level voltage; and a voltage delay section that is connected to the Schmitt trigger circuit and delays the voltage output by the Schmitt trigger circuit to output.

Preferably, the constant current generating section includes a constant current source which generates a current with a constant magnitude; and a first NMOS transistor of which the gate is connected to the drain thereof, the drain is connected to the constant current source, and the source thereof is grounded.

Preferably, the current mirroring section includes second and third NMOS transistors of which the gates are connected to the constant current generating section and the sources thereof are grounded; a first PMOS transistor of which the gate is connected to the source thereof, the source is connected to the drain of the second NMOS transistor, and the drain is connected to a power supply for driving the oscillator; a second PMOS transistor of which the gate is connected to the gate of the first PMOS transistor and the drain is connected to the power supply; a second NMOS transistor of which the gate is connected to the constant current generating section, the drain is connected to the source of the first PMOS transistor, and the source is grounded; and a third NMOS transistor of which the gate is connected to the constant current generating section, the drain is connected to the control section, and the source is grounded. In this case, the first NMOS transistor has the same capacity as those of the second and third NMOS transistors.

Preferably, the control section includes a third PMOS transistor of which the gate is connected to the voltage delay section, the drain is connected to the source of the second PMOS transistor, and the source is connected to the capacitor; and a fourth NMOS transistor of which the gate is connected to the voltage delay section, the drain is connected to the source of the third PMOS transistor, and the source is connected to the drain of the third NMOS transistor.

Preferably, the Schmitt trigger circuit includes a voltage generating section which generates high and low transition voltages to supply through high and low terminals, respectively; a comparator having a non-inverting terminal connected to the one end of the capacitor and an inverting terminal connected to the voltage generating section, the comparator comparing the voltage charged in the capacitor with the voltage supplied from the voltage generating section so as to output a high- or low-level voltage; a first switching unit having one end connected to the non-inverting terminal of the comparator and the other end connected to the high terminal of the voltage generating section, the first switching unit supplying or blocking the high transition voltage to the comparator; and a second switching unit having one end connected to the non-inverting terminal of the comparator and the other end connected to the low terminal of the voltage generating section, the second switching unit supplying or blocking the low transition voltage to the comparator. In this case, the voltage generating section is a bandgap reference voltage generating circuit.

Preferably, the voltage delay section includes a first inverter which is connected to the Schmitt trigger circuit and inverts the voltage output from the Schmitt trigger circuit to output; and a second inverter which is connected to the first inverter and re-inverts the voltage inverted by the first inverter to output.

The first switching unit of the Schmitt trigger circuit may be switched by the voltage output from the first inverter of the voltage delay section. Further, the second switching unit of the Schmitt trigger circuit may be switched by the voltage output from the second inverter of the voltage delay section.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a circuit diagram of a conventional oscillator using delay cells.

FIG. 2 is a circuit diagram of another conventional oscillator using a Schmitt trigger circuit;

FIG. 3 is a circuit diagram of the Schmitt trigger circuit used in the conventional oscillator of FIG. 2;

FIG. 4 is a diagram showing the waveform of the Schmitt trigger circuit used in the conventional oscillator of FIG. 2;

FIG. 5 is a diagram showing the output voltage waveform of the conventional oscillator using a Schmitt trigger circuit;

FIG. 6 is a schematic circuit diagram of an oscillator using a Schmitt trigger circuit according to the present invention; and

FIG. 7 is a diagram showing the output voltage waveform of a Schmitt trigger circuit used in the oscillator according to the invention.

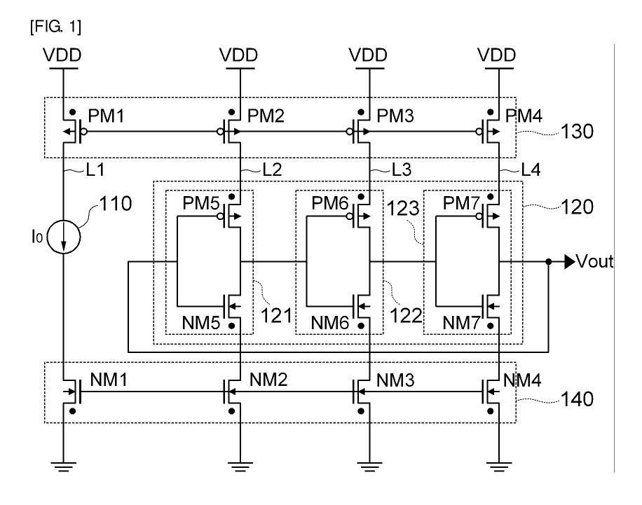

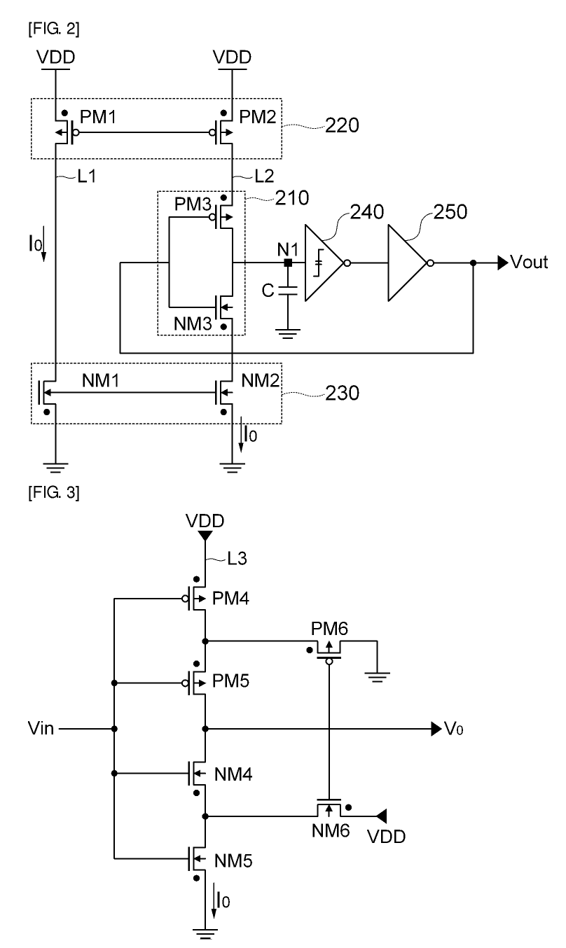

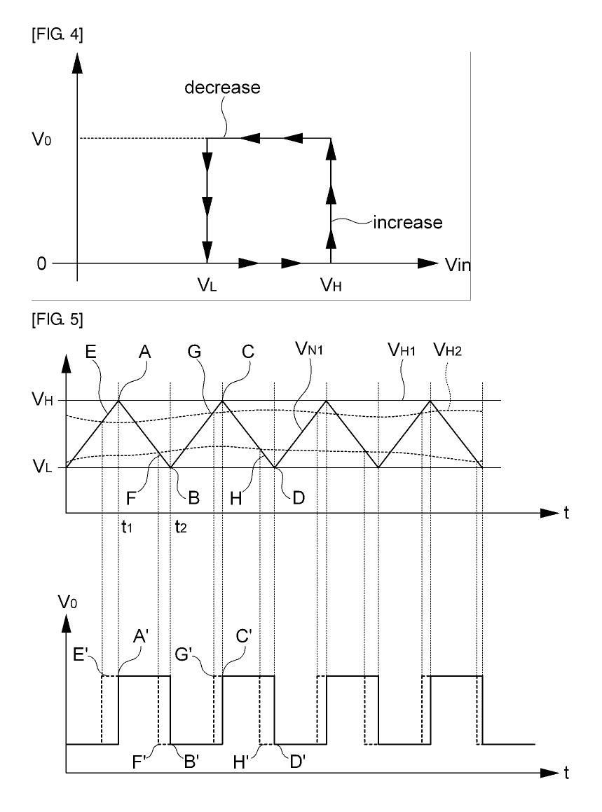

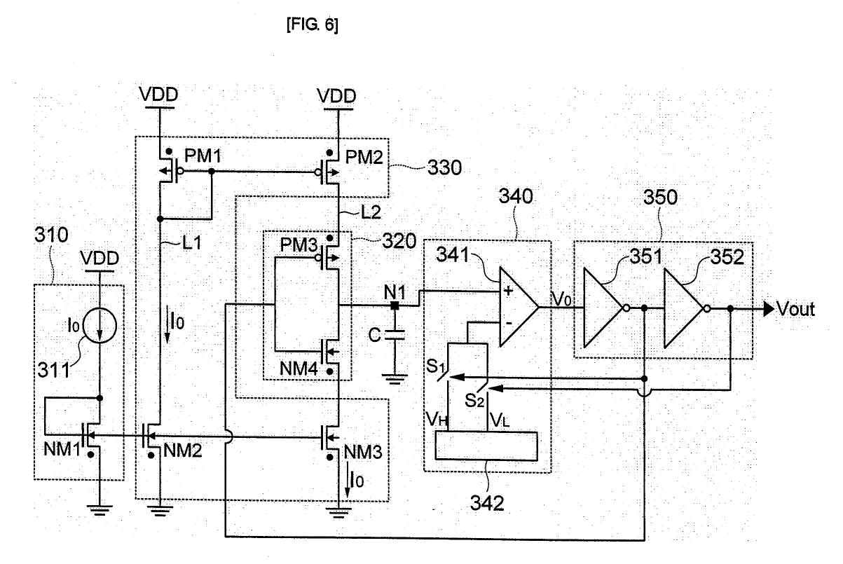

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, an oscillator using a Schmitt trigger circuit according to an embodiment of the present invention will be described in detail with reference to the accompanying drawings.

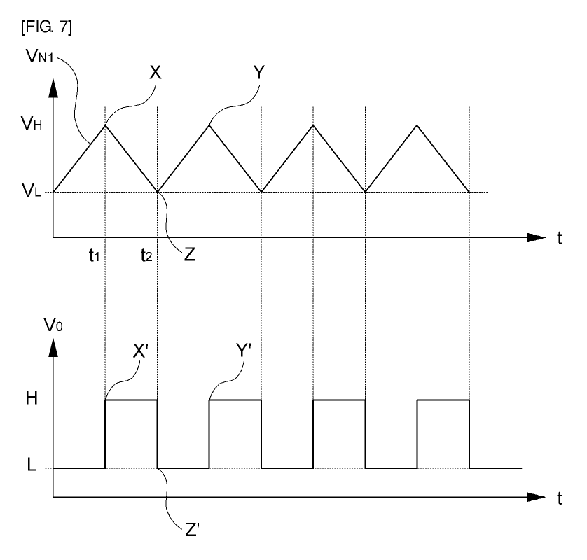

FIG. 6 is a schematic circuit diagram of an oscillator using a Schmitt trigger circuit according to the present invention. FIG. 7 is a diagram showing the output voltage waveform of a Schmitt trigger circuit used in the oscillator according to the invention.

As shown in FIG. 6, the oscillator using a Schmitt trigger circuit according to the invention includes first and second cell lines L1 and L2, a constant current generating section 310, a control section 320, a capacitor C, a current mirroring section 330, a Schmitt trigger circuit 340, and a voltage delay section 350.

The constant current generating section 310, which is composed of a constant current source 311 and a first NMOS transistor NM1, serves to generate a constant current.

The constant current source 311 generates and outputs a constant current I₀ with a constant magnitude. The gate of the first NMOS transistor NM1 is connected to the drain thereof, and the drain is connected to the constant current source 311. Further, the source of the first NMOS transistor NM1 is grounded so as to ground the constant current I₀ applied from the constant current source 311.

The current mirroring section 330 is composed of the first and second cell lines L1 and L2, first and second PMOS transistors PM1 and PM2, and second and third NMOS transistors NM1 and NM2. The current mirroring section 330 receives the constant current I₀, generated from the constant current generating section 310, through the first cell line L1, and then delivers the constant current I₀ to the second cell line L2.

The first PMOS transistor PM1 is provided on the first cell line L1. The gate of the first PMOS transistor PM1 is connected to the gate of the second PMOS transistor PM2, the drain thereof is connected to a power supply VDD for driving the oscillator, and the source thereof is connected to the drain of the second NMOS transistor NM2.

The second PMOS transistor PM2 is provided on the second cell line L2. The gate of the second PMOS transistor PM2 is connected to the gate of the first PMOS transistor PM1, the drain thereof is connected to the power supply VDD for driving the oscillator, and the source thereof is connected to the control section 320.

The second NMOS transistor NM2 is provided on the first cell line L1. The gate of the second NMOS transistor NM2 is connected to the gate of the first NMOS transistor NM1 of the constant current generating section 310, the drain thereof is connected to the source of the first PMOS transistor PM1, and the source thereof is grounded.

The third NMOS transistor NM3 is provided on the second cell line L2. The gate thereof is connected to the gates of the first and second transistors NM1 and NM2, the drain thereof is connected to the connected to the control section 320, and the source thereof is grounded.

As for the second and third NMOS transistors NM2 and NM3, it is preferable to use transistors with the same capacity as that of the first NMOS transistor NM1. The reason is as follows. Since the gate of the first NMOS transistor NM1 is connected to the gates of the second and third NMOS transistors NM2 and NM3, the first to third NMOS transistors NM1 to NM3 are turned on by the constant current I₀ which is the same gate signal. Further, the magnitude of current flowing in each of the transistors is determined by the constant current I₀ and a gate-source voltage V_{GS}. Accordingly, when the capacities of the respective NMOS transistors NM1 to NM3 are different from one another, currents flowing in the respective transistors have different values from one another. Therefore, it is preferable that the first to third NMOS transistors NM1 to NM3 have the same capacity.

The control section 320, which is composed of a third PMOS transistor PM3 and a fourth NMOS transistor NM4, receives an oscillation signal Vout output from the oscillator and then selects any one of the third PMOS transistor PM3 and the fourth NMOS transistor NM4 so as to output a high- or low-level voltage.

The third PMOS transistor PM3 receives the oscillation signal Vout, output from the oscillator, through the gate thereof. The drain of the third PMOS transistor PM3 is connected to the source of the second PMOS transistor PM2 of the current mirroring section 330, and the source thereof is connected to the drain of the fourth NMOS transistor NM4.

The gate of the fourth NMOS transistor NM4 is connected to the gate of the third PMOS transistor PM3 such that the oscillation signal Vout output from the oscillator is received through the gate. The drain of the fourth NMOS transistor NM4 is connected to the source of the third PMOS transistor PM3, and the source thereof is connected to the drain of the third NMOS transistor NM3 of the current mirroring section 330.

One end of the capacitor C is connected to a contact point N1 between the source of the third PMOS transistor PM3 and the drain of the fourth NMOS transistor NM4, and the other end thereof is grounded so as to be charged with a voltage output from the control section 310.

The Schmitt trigger circuit 340, which is composed of a comparator 341, first and second switching units S1 and S2, and a voltage generating section 342, receives the voltage of the contact point N1 charged in the capacitor C so as to output a pulse-type square-wave voltage.

A non-inverting terminal (+) of the comparator 341 is connected to one end of the capacitor C, that is, the contact point N1, and an inverting terminal (−) thereof is connected to one ends of the first and second switching units S1 and S2. The comparator 341 compares the voltage charged in the capacitor C with a voltage applied through the first or second switching unit S1 or S2 so as to output a high- or low-level output voltage Vo.

The voltage generating section 342 has high and low terminals which generate high and low transition voltages V_{H} and V_{L}, respectively, and then supply the voltages to the outside. Through the switching unit selected between the first and second switching units S1 and S2, the voltage generating section 342 supplies a high or low transition voltage V_{H} or V_{L} to the inverting terminal (−) of the comparator 341.

As for the voltage generating section 342, a bandgap-reference voltage generating circuit may be used, which has a constant voltage despite a change in surrounding environment such as temperature, voltage or the like.

One end of the first switching unit S1 is connected to the inverting terminal (−) of the comparator 341, and the other end thereof is connected to the high terminal of the voltage generating section 342. As the first switching unit S1 is turned on/off by a voltage applied from the voltage delay section 350, the first switching unit S1 supplies or blocks the high transition voltage V_{H} to the comparator 341.

One end of the second switching unit S2 is connected to the inverting terminal (−) of the comparator 341, and the other end thereof is connected to the low terminal of the voltage generating section 342. As the second switching unit S2 is turned on/off by a voltage applied from the voltage delay section 350, the second switching unit S2 supplies or blocks the low transition voltage V_{L} to the comparator 341.

The voltage delay section 350 is composed of first and second inverters 351 and 352 and is connected to the Schmitt trigger circuit 340. The voltage delay section 350 receives a square-wave output voltage Vo from the Schmitt trigger circuit 340 and then delays the square-wave output voltage Vo for a predetermined time to output.

The first inverter 351 receives the output voltage Vo output from the Schmitt trigger circuit 340 and then transfers the output voltage Vo to output. The transferred voltage is supplied to the first switching unit S1. The second inverter 352 re-transfers the transferred voltage from the first switching unit S1 and then supplies the re-transferred voltage to the second switching unit S2. Through the above-described process, the first and second switching units S1 and S2 are turned on/off.

The oscillator constructed in such a manner is driven by the following process. First, as the first and second NMOS transistors NM1 and NM2 are turned on by the constant current I₀ generated by the constant current generating section 310, a current having the same magnitude as that of the constant current I₀ flows in the first cell line L1.

At this time, the current I₀ flowing in the first cell line L1 is caused to flow in the second cell line L2 by the current mirroring section 330. When the voltage received from the voltage delay section 350 is a low-level voltage, the control section 320 turns on the third PMOS transistor PM3 so as to charge the capacitor C. When the voltage is a high-level voltage, the control section turns on the fourth NMOS transistor NM4 so as to ground the capacitor C through the third NMOS transistor NM3.

Therefore, the Schmitt trigger circuit 340 receives the voltage of the capacitor C which is charged and discharged by the control section 320. Then, as shown in FIG. 7, when a point of time where the voltage charged in the capacitor C, that is, a voltage V_{N1} applied to the contact point N1 increases to the high transition voltage V_{H} is X, the output voltage Vo is transferred from low level to high level at a point of time X′. Further, when a point of time where the voltage V_{N1} decreases to the low transition voltage V_{L} is Z, the output voltage Vo is transferred from high level to low level at a point of time Z′.

As described above, the oscillator using a Schmitt trigger circuit according to the invention uses the constant current source 311 which generates the constant current I₀ despite a change in surrounding environment. Therefore, the oscillator can constantly maintain a voltage supplied to the Schmitt trigger circuit 340, which makes it possible to constantly maintain the frequency of an oscillation signal Vout generated from the oscillator.

Further, the Schmitt trigger circuit 340 uses the comparator 341 and the voltage generating section 342 which generates the high or low transition voltage V_{H} or V_{L} with a constant magnitude depending on a change in surrounding environment. Therefore, the oscillator can generate an oscillation signal Vout with a constant frequency.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An oscillator using a Schmitt trigger circuit, comprising:
a constant current generating section that generates a current with a constant magnitude;
a current mirroring section that is connected to the constant current generating section and mirrors the current generated by the constant current generating section;
a control section that is connected to the current mirroring section and supplies or blocks the current applied through the current mirroring section;
a capacitor of which one end is connected to the control section and the other end is grounded, the capacitor being charged with a current supplied by the control section;
a Schmitt trigger circuit that receives the voltage charged in the capacitor so as to output a high- or low-level voltage; and
a voltage delay section that is connected to the Schmitt trigger circuit and delays the voltage output by the Schmitt trigger circuit to output.

2. The oscillator according to claim 1, wherein the constant current generating section includes:
a constant current source which generates a current with a constant magnitude; and
a first NMOS transistor of which the gate is connected to the drain thereof, the drain is connected to the constant current source, and the source thereof is grounded.

3. The oscillator according to claim 2, wherein the current mirroring section includes:
second and third NMOS transistors of which the gates are connected to the constant current generating section and the sources thereof are grounded;
a first PMOS transistor of which the gate is connected to the source thereof, the source is connected to the drain of the second NMOS transistor, and the drain is connected to a power supply for driving the oscillator;
a second PMOS transistor of which the gate is connected to the gate of the first PMOS transistor and the drain is connected to the power supply;
a second NMOS transistor of which the gate is connected to the constant current generating section, the drain is connected to the source of the first PMOS transistor, and the source is grounded; and
a third NMOS transistor of which the gate is connected to the constant current generating section, the drain is connected to the control section, and the source is grounded.

4. The oscillator according to claim 3, wherein the first NMOS transistor has the same capacity as those of the second and third NMOS transistors.

5. The oscillator according to claim 3, wherein the control section includes:
a third PMOS transistor of which the gate is connected to the voltage delay section, the drain is connected to the source of the second PMOS transistor, and the source is connected to the capacitor; and
a fourth NMOS transistor of which the gate is connected to the voltage delay section, the drain is connected to the source of the third PMOS transistor, and the source is connected to the drain of the third NMOS transistor.

6. The oscillator according to claim 1, wherein the Schmitt trigger circuit includes:
a voltage generating section which generates high and low transition voltages to supply through high and low terminals, respectively;
a comparator having a non-inverting terminal connected to the one end of the capacitor and an inverting terminal connected to the voltage generating section, the comparator comparing the voltage charged in the capacitor with the voltage supplied from the voltage generating section so as to output a high- or low-level voltage;
a first switching unit having one end connected to the non-inverting terminal of the comparator and the other end connected to the high terminal of the voltage generating section, the first switching unit supplying or blocking the high transition voltage to the comparator; and
a second switching unit having one end connected to the non-inverting terminal of the comparator and the other end connected to the low terminal of the voltage generating section, the second switching unit supplying or blocking the low transition voltage to the comparator.

7. The oscillator according to claim 6, wherein the voltage generating section is a bandgap reference voltage generating circuit.

8. The oscillator according to claim 1, wherein the voltage delay section includes:
a first inverter which is connected to the Schmitt trigger circuit and inverts the voltage output from the Schmitt trigger circuit to output; and
a second inverter which is connected to the first inverter and re-inverts the voltage inverted by the first inverter to output.

9. The oscillator according to claim 6, wherein the first switching unit of the Schmitt trigger circuit is switched by the voltage output from the first inverter of the voltage delay section.

10. The oscillator according to claim 6, wherein the second switching unit of the Schmitt trigger circuit is switched by the voltage output from the second inverter of the voltage delay section.
